(19) United States
(12) Patent Application Publication
(10) Pub. No.: US 2005/0127446 A1
(43) Pub. Date: Jun. 16, 2005

(54) Semiconductor device and method for manufacturing semiconductor device

(75) Inventors: Kentaro Nakanishi, Nara (JP); Atsuhiro Kajiya, Hyogo (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/984,860

(22) Filed: Nov. 10, 2004

(30) Foreign Application Priority Data
Dec. 10, 2003 (JP) 2003-411966

(51) Int. Cl. H01L 29/76

(52) U.S. Cl. 257/358

(57) ABSTRACT

With this method for manufacturing a semiconductor device, a gate insulating film is formed on a semiconductor substrate, and a polysilicon thin film is formed on the gate insulating film. A plasma nitriding process is then performed, thereby introducing nitrogen into the polysilicon thin film. A polysilicon film is next formed on the polysilicon thin film and the plasma nitriding process is performed, thereby forming a nitrogen-containing region having a depth of 10 nm or less in an upper portion of the polysilicon film. The polysilicon film is patterned to form a gate electrode. SD extensions are then formed in the semiconductor substrate, a sidewall is formed on a side surface of the gate electrode, and source and drain regions are then formed in the semiconductor substrate.

### CROSS REFERENCE TO RELATED APPLICATIONS

This application claims priority under 35 U.S.C § 119 on Patent Application No. 2003-411966 filed in Japan on Dec. 10, 2003, the entire contents of which are hereby incorporated by reference.

### BACKGROUND OF THE INVENTION

The present invention relates to a p-type semiconductor device and a method for manufacturing the p-type semiconductor device. More specifically, the present invention relates to a gate insulating type semiconductor device doped with boron as p-type impurities and a manufacturing method therefor.

A semiconductor device having a metal oxide semiconductor (MOS) transistor structure has been widely used for an electronic device since a silicon oxide film that is an oxide of silicon (semiconductor) exhibits a good insulating characteristic as a gate insulating film. To improve a performance of this MOS transistor, it is effective to perform scaling such as reduction in a gate length of the transistor and reduction in a thickness of the gate insulating film. In recent years, this scaling approach has accelerated.

In a PMOS transistor, a gate electrode contains boron which is p-type impurities. When a heat treatment is carried out during a semiconductor process, this boron is diffused toward a gate insulating film and a silicon substrate from the gate electrode (which phenomenon is referred to as “boron-causing alloy spike”). As a result of boron diffusion to surroundings of the gate electrode, a transistor characteristic fluctuates. This has been considered a serious defect for a recent semiconductor manufacturing technique in which a reduction in the thickness of the gate insulating film is underway. To prevent this defect, a method for forming a gate oxynitride film having nitride introduced into the gate insulating film (“an oxynitride process”) has been widely adopted.

On the other hand, negative bias temperature instability (“NBTI”) is pointed out as a phenomenon that causes a fluctuation in the characteristic of the PMOS transistor. The NBTI is a phenomenon that, when a negative voltage is applied to the gate electrode of the PMOS transistor in a high temperature atmosphere, presence of nitride near an interface between the gate insulating film and the substrate yields positive fixed charges, and the transistor characteristic fluctuates due to the influence of the positive fixed charges.

A plasma nitriding process used as measures against the NBTI will now be briefly described with reference to the drawings. FIGS. 7A to 7D are sections which depict steps of a plasma nitriding process performed on a gate insulating film of a conventional MOS transistor.

Among conventional steps, at a step shown in FIG. 7A, first, a gate insulating film 102 is formed on a semiconductor substrate 101. At a step shown in FIG. 7B, the plasma nitriding process is performed, thereby introducing nitride into the gate insulating film 102. At a step shown in FIG. 7C, a lithographic and dry-etching step is performed after a polysilicon film (not shown) is deposited on the substrate 101, thereby forming a gate electrode 103. At a step shown in FIG. 7D, p-type ions are implanted while using the gate electrode 103 as a mask, thereby forming source-drain (SD) extensions 104 in portions of the semiconductor substrate 101 which portions are located sideways of the gate electrode 103. Thereafter, a sidewall 107 composed of an L-shaped oxide film 105 and a nitride film 106 is formed sideways of the gate electrode 103. Using the gate electrode 103 and the sidewall 107 as a mask, p-type ions are implanted, thereby forming a source-drain diffused layer 108 in regions of the semiconductor substrate 101 which regions are located sideways of the sidewall 107. Through these steps, a transistor can be manufactured.

A nitrogen profile of the transistor thus manufactured by the plasma nitriding process will be described. FIG. 8 is a graph which depicts secondary ion mass spectroscopy (SIMS) profiles of nitrogen taken along a line A-A of FIG. 7D. In FIG. 8, a curve indicated by a group of black circles indicates a nitrogen SIMS profile when the gate insulating film formed at the steps shown in FIGS. 7A to 7D is used. A curve indicated by a group of white circles indicates a nitrogen SIMS profile when an oxynitride film formed by oxynitriding the silicon substrate under an atmosphere containing nitrogen monoxide and oxygen (formed by an NO/O₂ oxynitride process) is used as the gate insulating film.

As shown in FIG. 8, if the plasma nitriding process is performed, a nitrogen concentration peak is present on a surface side of the gate insulating film and a nitrogen concentration on the interface between the gate insulating film and the substrate is low, as compared with the NO/O₂ oxynitride process. Therefore, it is possible to more suppress deterioration in NBTI characteristic due to the positive fixed charges resulting from nitriding when the plasma nitriding process is performed. If the plasma nitriding process is performed, a nitrogen peak concentration in the gate insulating film is as high as 10 atoms %. Therefore, the alloy spike caused by boron from the gate electrode can be suppressed. As can be seen, the method for forming the gate insulating film by the plasma nitriding process can both suppress the alloy spike caused by gate boron and ensure the NBTI characteristic. It is, therefore, considered hat the method will be more popular in the future.

However if the reduction in the thickness of the gate insulating film is further progressed, it is suspected that it is difficult to optimize conditions for the plasma nitriding process. That is, if the gate insulating film is made thinner, it is difficult to secure a nitrogen amount which can suppress the alloy spike caused by the gate boron while suppressing nitriding of the interface between the gate insulating film and the substrate.

To solve this disadvantage, such measures as disclosed in, for example, Japanese Patent Application Laid-Open No. 2002-289846 have been proposed. Namely, a boron diffusion prevention film containing nitrogen is formed on the gate insulating film, and then a gate electrode material is deposited. With this method, even if the gate insulating film is made thinner in the PMOS transistor, it is possible to suppress the boron-causing alloy spike by the boron diffusion prevention film and secure NBTI reliability.

However, even if the PMOS transistor disclosed in the Japanese Patent Application Laid-Open No. 2002-289846 can suppress boron in the gate electrode from being diffused to either the gate insulating film or the semiconductor substrate, diffusion of boron to an oxide film sidewall provided on a side surface of the gate electrode or to an oxide film provided above the gate electrode cannot be suppressed.

The diffusion of boron upward or sideways of the gat electrode will be briefly described with reference to FIGS. 9A and 9B. FIGS. 9A and 9B are sections which depict steps of forming silicide films for forming a low-resistance contact. Referring to FIGS. 9A and 9B, a transistor A indicates a transistor in which the silicide film is formed, and a transistor B indicates a transistor in which the silicide film is not formed. The transistor in which the silicide film is not formed is used as a resistance element in, for example, an I/O element (an element that constitutes an input and output circuit) or an analog element.

At steps shown in FIG. 9A, a gate electrode 113 of each of the transistors A and B and a sidewall 118 formed on a side surface of the gate electrode 113 are covered with a silicide protection oxide film 121. In this state, rapid thermal anneal (RTA) is carried out to activate source-drain regions 117.

At steps shown in FIG. 9B, a portion of the silicide protection oxide film 121 which portion is located on the transistor A is removed to expose an upper surface of the gate electrode 113 of the transistor A and upper portions of the sidewall 118. If siliciding is performed in this state, a silicide layer 122 is formed on the gate electrode 113 and the source-drain regions 117 of the transistor A. However, since an upper portion of the transistor B is covered with the silicide protection film 121, an upper portion of the gate electrode 113 and that of the source/drain regions 117 of the transistor B are not silicided.

If these steps are executed, boron in the gate electrode 113 is diffused to the silicide protection oxide film 121 and the sidewall 118, resulting in a reduction in a boron concentration of the gate electrode 113. This causes depletion of the gate electrode 113, and a reduction in a driving force.

### SUMMARY OF THE INVENTION

In view of the conventional disadvantages, the present invention has been achieved and an object thereof is to provide a semiconductor device which can improve a driving force by ensuring an NBTI characteristic and suppressing an alloy spike caused by boron contained in a gate electrode, and a method for manufacturing the semiconductor device.

According to one aspect of the present invention, there is provided a semiconductor device, comprising an element that comprises: a semiconductor layer; an insulating film which is provided above the semiconductor layer; a conductor film which is provided above the insulating film, and which contains p-type impurities; and a first nitrogen-containing region which is provided in at least part of an upper surface portion and a side surface portion of the conductor film, and which contains nitrogen.

It is noted that the semiconductor device comprises an element (a second element) including: a gate insulating film which is provided on part of the semiconductor layer, and which is formed out of the same film as the insulating film; and a gate electrode which is formed out of the same film as the conductor film is provided sideways of this element (first element). Simultaneously with forming the first nitrogen-containing region of the first element, nitrogen is introduced into at least part of an upper surface portion and a side surface portion of the gate electrode of this second element.

If the first element and the second element are provided as stated above, nitrogen is present in an uppermost surface portion of the gate electrode of the second element. As a result, even if a high-temperature heat treatment is performed, it is possible to prevent the p-type impurities contained in the gate electrode from being diffused upward and sideways, and prevent a reduction in a boron concentration of the gate electrode. Due to this, depletion of the gate electrode less occurs, and a driving force is not reduced.

In the semiconductor device, a second nitrogen-containing region, which is a nitrogen-containing conductor film, may be interposed between the insulating film and the conductor film. In this case, an amount of nitrogen present near an interface between the gate insulating film and the semiconductor layer is reduced. Therefore, even if a reduction in a thickness of the gate insulating film is progressed, it is possible to prevent deterioration in an NBTI characteristic resulting from nitrogen.

Preferably, the first nitrogen-containing region is provided within a range at a depth of equal to or more than 10 nm from an upper surface or a side surface of the conductor film. The introduction of the nitrogen into such a shallow region can be realized by using a plasma nitriding process. Because of the fact that nitrogen is locally contained in the shallow region, it is possible to more effectively prevent diffusion of the p-type impurities, and satisfactorily maintain characteristics of other regions in the gate insulating film.

In the semiconductor device, a sidewall may be provided on a side surface of the conductor film, a first impurity diffused layer that contains the p-type impurities may be provided in a portion of the semiconductor layer which portion is located sideways of the conductor film, and a second impurity diffused layer that contains the p-type impurities higher in concentration than the p-type impurities of the first impurity diffused layer may be provided in a portion of the semiconductor layer which portion is located sideways of the sidewall.

In the semiconductor device, a third nitrogen-containing region that contains the nitrogen may be provided above the second impurity diffused layer. In this case, it is possible to prevent the p-type impurities contained in the second impurity diffused layer from being diffused upward.

In the semiconductor device, an oxynitride film may be provided on at least part of a side surface and an upper surface of the conductor film.

If the p-type impurities are boron, a greater advantage can be attained by applying the present invention to the semiconductor device.

It is preferable that a peak concentration of the nitrogen contained in the element is equal to or higher than 5 atoms % and equal to or lower than 20 atoms %.

It is preferable that the conductor film consists of one of polysilicon, amorphous silicon, germanium-containing polysilicon, and germanium-containing amorphous silicon. If the conductor film contains germanium, an activation ratio of the p-type impurities in the gate electrode can be improved, and the driving force of the semiconductor device can be improved.

In the semiconductor device, the insulating film may be a gate insulating film, and the conductor film may be a gate electrode. Specific examples of such a semiconductor device include a semiconductor device wherein the first element is an input and output (I/O) element and the second element constitutes a logic circuit section. In this example, after nitrogen is introduced into the I/O element and the logic circuit, it often occurs that a silicide layer is formed in an upper portion of the gate electrode in the logic circuit section, but that no silicide layer is formed in an upper portion of the conductor film in the I/O element. To form the silicide layer only in one of the elements on one wafer, siliciding is performed while the element in which no silicide layer is formed is covered with an oxide film or the like. Since it is necessary to perform a high-temperature heat treatment so as to form the silicide layer, boron contained in the element in which no silicide layer is formed is conventionally diffused to the oxide film or the like. However, in the semiconductor device of the present invention, since the nitrogen-containing region is provided, it is possible to suppress diffusion of boron contained in the gate electrode.

Another example of the semiconductor device is a semiconductor device wherein the first element is a DRAM and the second element is a logic circuit in a DRAM embedded logic process. Further, the present invention can be applied to a semiconductor device that includes a region in which a silicide layer is formed so as to realize a high-rate operation, and a region in which no silicide layer is formed so as to secure resistance against high voltage.

In the semiconductor device, the element may be a resistance element. Specifically, the first element may be a resistance element, and the second element which serves as an actually operating element may be provided in a region of the semiconductor layer other than the region in which the first element is present. In this case, after nitrogen is introduced into the resistance element and the actually operating element, it often occurs that the silicide layer is formed in the upper portion of the gate electrode in the actually operating element, but that no silicide layer is formed in the upper portion of the conductor film in the resistance element. According to the present invention, the nitrogen-containing region is provided in the semiconductor device. Therefore, even if a heat treatment is performed so as to form the silicide layer, the boron diffusion can be suppressed.

According to another aspect of the present invention, there is provided a first method for manufacturing a semiconductor device, comprising: a step (a) of forming a gate insulating film on a semiconductor layer; a step (b), after the step (a), of forming a conductor film above the gate insulating film; a step (c), after the step (b), of forming a first nitrogen-containing region by introducing nitrogen into an upper portion of the conductor film; a step (d), after the step (c), of forming a gate electrode by patterning the conductor film; and a step (e), after the step (d), of forming a first impurity layer in a region of the semiconductor layer which region is located sideways of the gate electrode, by introducing p-type impurities into the semiconductor layer while using the gate electrode as a mask. The p-type impurities may be introduced into the gate electrode at the step (e) or may be introduced in advance.

In this case, nitrogen is present in an uppermost surface portion of the gate electrode. As a result, even if a high-temperature heat treatment is performed, it is possible to prevent the p-type impurities contained in the gate electrode from being diffused upward and sideways, and prevent a reduction in a boron concentration of the gate electrode. Therefore, the semiconductor device to which depletion of the gate electrode less occurs, and which has a high driving force can be obtained.

The method may further comprise, after the step (e), a step (f) of forming a sidewall on a side surface of the gate electrode, and a step (g) of forming a second impurity layer in a portion of the semiconductor layer which portion is located sideways of the sidewall by introducing the p-type impurities into the semiconductor layer while using the sidewall as the mask.

The method may further comprise, after the step (a) and before the step (b), a step (h) of forming a thin film conductor layer on the gate insulating film, and of forming a second nitrogen-containing region by introducing the nitrogen into the thin film conductor layer. In addition, at the step (b), the conductor film may be formed on the second nitrogen-containing region. In this case, an amount of nitrogen present near an interface between the gate insulating film and the semiconductor layer can be reduced. Therefore, the semiconductor device to which deterioration in an NBTI characteristic resulting from nitrogen less occurs can be obtained.

The method may further comprise, after the step (d) and before the step (e), a step (i) of forming an oxynitride film that covers a side surface of the gate electrode.

At the step (i), an oxide film that covers the gate electrode may be formed on the semiconductor layer, said oxynitride film is formed by introducing nitrogen into said oxide film, and then a portion of the oxynitride film which portion is located on at least the semiconductor layer may be removed.

At the step (i), an oxide film that covers the gate electrode may be formed on the semiconductor layer, a portion of said oxide film which portion is located on at least said semiconductor layer is removed, and then the oxynitride film may be formed by introducing the nitrogen into the oxide film.

According to yet another aspect of the present invention, there is provided a second method for manufacturing a semiconductor device, comprising: a step (a) of forming a gate insulating film on a semiconductor layer; a step (b), after the step (a), of forming a conductor film above the gate insulating film; a step (c), after the step (b), of forming a gate electrode by patterning the conductor film; a step (d), after the step (c), of forming a first nitrogen-containing region by introducing nitrogen into at least part of an upper surface portion and a side surface portion of the gate electrode; and a step (e) of forming a first impurity layer in a region of the semiconductor layer which region is located sideways of the gate electrode by introducing p-type impurities into the semiconductor layer while using the gate electrode as a mask.

In this case, nitrogen is present in an uppermost surface portion of the gate electrode. As a result, even if a high-temperature heat treatment is performed, it is possible to prevent the p-type impurities contained in the gate electrode from being diffused upward and sideways, and prevent a reduction in a boron concentration of the gate electrode. Therefore, the semiconductor device to which depletion of the gate electrode less occurs, and which has a high driving force can be obtained.

The method may further comprise, after the step (e), a step (f) of forming a sidewall on a side surface of the gate electrode, and a step (g) of forming a second impurity layer in a portion of the semiconductor layer which portion is located sideways of the sidewall by introducing the p-type impurities into the semiconductor layer while using the sidewall as the mask.

The method may further comprise, after the step (a) and before the step (b), a step (h) of forming a thin film conductor layer on the gate insulating film, and of forming a second nitrogen-containing region by introducing the nitrogen into the thin film conductor layer. In addition, at the step (b), the conductor film may be formed on the second nitrogen-containing region. In this case, an amount of nitrogen present near an interface between the gate insulating film and the semiconductor layer can be reduced. Therefore, the semiconductor device to which deterioration in an NBTI characteristic resulting from nitrogen from less occurs can be obtained.

At the step (d), the nitrogen may be introduced while a resist covers the semiconductor layer. If so, the method has an advantage in that, even if nitrogen is introduced at strong energy, the nitrogen is not introduced up to a deep region of the semiconductor layer.

At the step (d), a third nitrogen-containing region may be formed in an upper portion of the semiconductor layer.

According to still another aspect of the present invention, there is provided a third method for manufacturing a semiconductor device, comprising: a step (a) of forming a gate insulating film on a semiconductor layer; a step (b), after the step (a), of forming a conductor film above the gate insulating film; a step (c), after the step (b), of forming a gate electrode by patterning the conductor film; a step (d), after the step (c), of forming a first impurity layer in a region of the semiconductor layer which region is located sideways of the gate electrode by introducing p-type impurities into the semiconductor layer while using the gate electrode as a mask; a step (e), after the step (d), of forming a sidewall on a side surface of the gate electrode; a step (f) of forming a second impurity layer in a portion of the semiconductor layer which portion is located sideways of the sidewall by introducing the p-type impurities into the semiconductor layer while using the sidewall as a mask; and a step (g), after the step (f), of forming a nitrogen-containing region in an upper portion of the gate electrode and in an upper portion of the second impurity layer in the semiconductor layer by supplying nitrogen from above the semiconductor layer.

In this case, nitrogen is present in an uppermost surface portion of the gate electrode. As a result, even if a high-temperature heat treatment is performed, it is possible to prevent the p-type impurities contained in the gate electrode from being diffused upward and sideways, and prevent a reduction in a boron concentration of the gate electrode. Therefore, the semiconductor device to which depletion of the gate electrode less occurs, and which has a high driving force can be obtained.

The method may further comprise, after the step (a) and before the step (b), a step (h) of forming a thin film conductor layer on the gate insulating film, and of introducing the nitrogen into the thin film conductor layer. In addition, at the step (b), the conductor film may be formed on the thin film conductor layer. In this case, an amount of nitrogen present near an interface between the gate insulating film and the semiconductor layer can be reduced. Therefore, the semiconductor device to which deterioration in an NBTI characteristic resulting from nitrogen from less occurs can be obtained.

### BRIEF DESCRIPTION OF THE DRAWINGS

FIGS. 1A to 1E are sections that depict a method for manufacturing a semiconductor device according to a first embodiment of the present invention.

FIGS. 2A to 2F are sections that depict a method for manufacturing a semiconductor device according to a second embodiment of the present invention.

FIGS. 3A to 3F are sections that depict a method for manufacturing a semiconductor device according to a third embodiment of the present invention.

FIGS. 4A to 4F are sections that depict a method for manufacturing a semiconductor device according to a fourth embodiment of the present invention.

FIGS. 5A to 5F are sections that depict a method for manufacturing a semiconductor device according to a fifth embodiment of the present invention.

FIGS. 6A to 6F are sections that depict a method for manufacturing a semiconductor device according to a sixth embodiment of the present invention.

FIGS. 7A to 7D are sections that depict steps of a plasma nitriding process performed on a gate insulating film of a conventional MOS transistor.

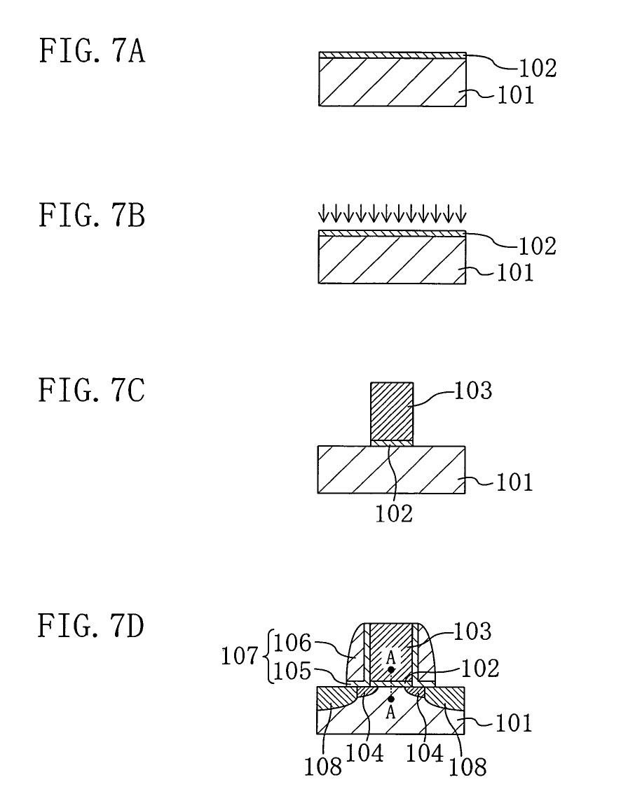

FIG. 8 is a graph which depicts nitrogen SIMS profiles taken along a line A-A of FIG. 7D.

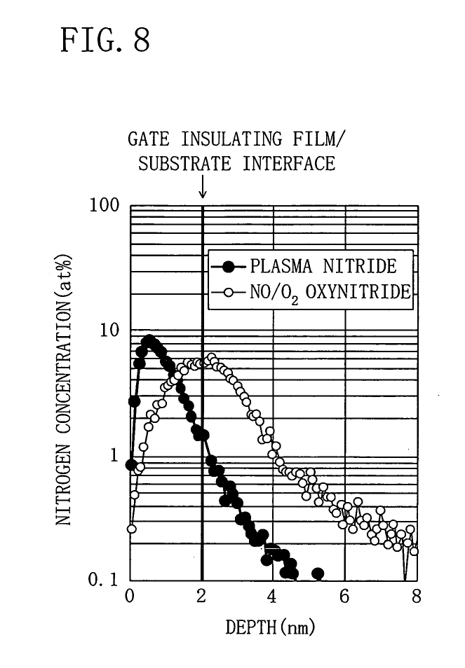

FIGS. 9A and 9B are sections that depict steps of forming silicide films for forming a low-resistance contact.

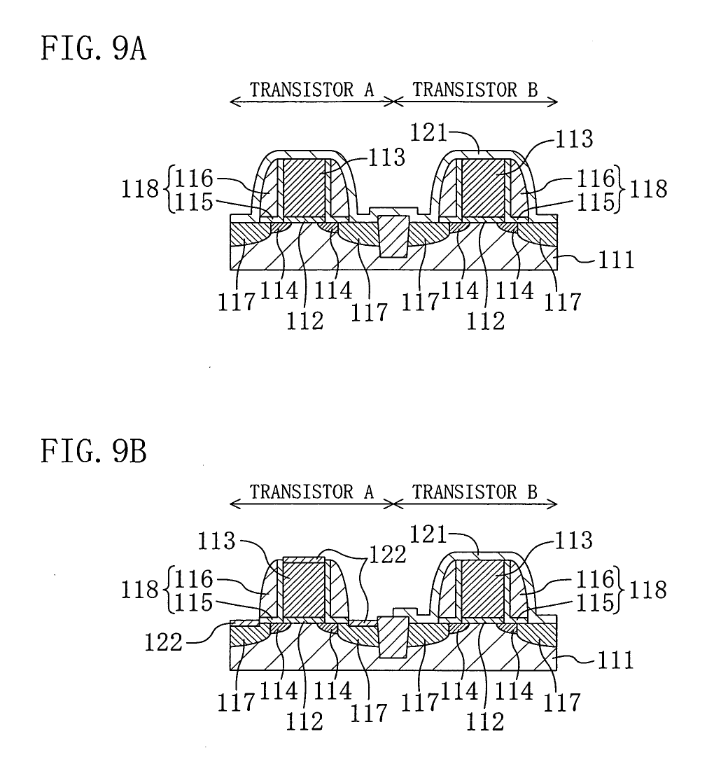

### DETAILED DESCRIPTION OF THE INVENTION

Hereinafter, preferred embodiments of the present invention will be described with reference to the accompanying drawings, in which the same reference numerals denote the same components, respectively.

### Embodiment 1

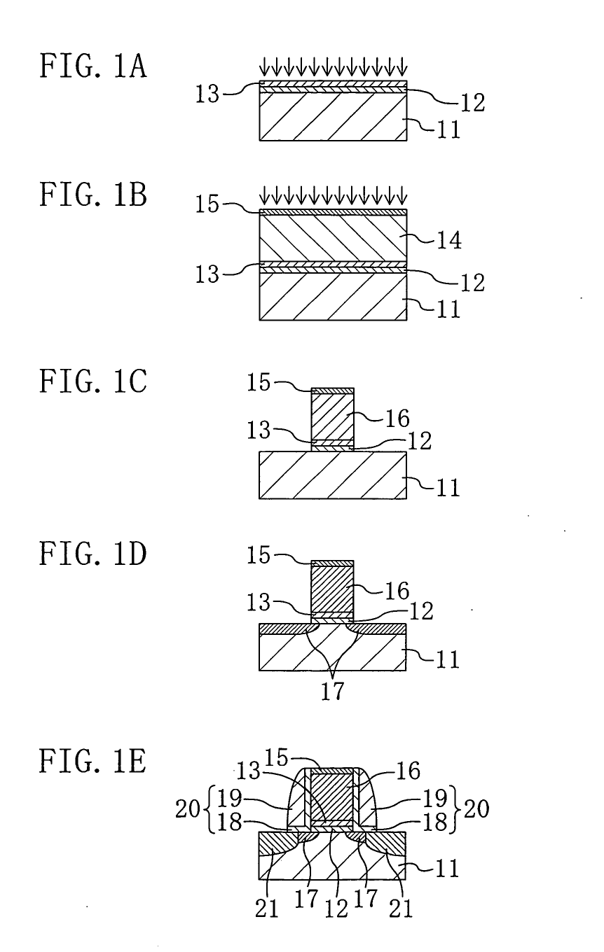

A first embodiment of the present invention will be described hereinafter with reference to the drawings. FIGS. 1A to 1E are sections that depict a method for manufacturing a semiconductor device according to the first embodiment of the present invention.

In the semiconductor device manufacturing method according to the first embodiment, at a step shown in FIG. 1A, a gate insulating film 12 having a thickness of 2.0 nm is formed on a semiconductor substrate 11. Thereafter, a polysilicon thin film 13 having a thickness of 10 nm is deposited on the gate insulating film 12, and a plasma nitriding process is performed (at a pressure of 950 mT (126 Pa), at a temperature of 400° C., and for a time of 20 sec), thereby introducing nitride into the polysilicon thin film 13. At this time, by thus introducing nitrogen by the plasma nitriding process, a peak nitrogen concentration can be set at a position near an upper surface of the polysilicon thin film 13.

At a step shown in FIG. 1B, a polysilicon film 14 having a thickness of 150 nm is deposited on the polysilicon thin film 13, and then the plasma nitriding process is performed (at a pressure of 500 mT (67 Pa), at a temperature of 400° C., and for a time of 20 sec), thereby forming a nitrogen-containing region 15 in a region from an upper surface of the polysilicon film 14 up to a depth of about 5 nm from the upper surface.

At a step shown in FIG. 1C, the polysilicon film 14 is patterned by lithography and dry etching, thereby forming a gate electrode 16. At the same time, the polysilicon thin film 13 is patterned. As a result, a nitrogen-containing region obtained by introducing nitrogen into the polysilicon thin film 13 is formed between the gate insulating film 12 and the gate electrode 16. In this embodiment, the polysilicon thin film 13 is discriminated from the gate electrode 16. However, this polysilicon thin film 13 functions as a part of the gate electrode 16.

At a step shown in FIG. 1D, boron is implanted into the substrate from above (at an energy of 0.5 KeV and a dosage of 4×10¹⁴ cm⁻¹, thereby forming SD extensions 17 in portions of the semiconductor substrate 11 which portions are located sideways of the gate electrode 16. At the same time, boron is implanted into the gate electrode 16.

At a step shown in FIG. 1E, a sidewall 20 composed of an oxide film 18 having an L-shaped cross section and a nitride film 19 located on the oxide film 18 is formed on a side surface of the gate electrode 16. Thereafter, boron is implanted into the substrate from above (at an energy of 3 KeV and a dosage of 3×10¹⁵ cm⁻²), thereby forming source-drain diffused layers 21 in portions of the semiconductor substrate 11 which portions are located sideways of the sidewall 20. Thereafter, a step of forming a silicide film and a wiring for forming a low-resistance contact is executed. However, since this step is the same as that of the conventional method, it will not be described herein.

In the semiconductor device according to the first embodiment, the nitrogen-containing region 15 in which nitrogen is present is formed on an uppermost portion of the gate electrode 16. This nitrogen-containing region 15 can prevent boron contained in the gate electrode 16 from being diffused upward of the gate electrode 16, and a boron concentration of the gate electrode 16 from being reduced. For example, even if an activation RTA treatment is performed while the gate electrode 16 is covered with a silicide protection oxide film, the nitrogen-containing region 15 can suppress the boron diffusion. Therefore, no boron is diffused from the gate electrode 16 to the silicide protection oxide film. As a result, depletion of the gate electrode 16 less occurs, and a driving force is not reduced.

Meanwhile, nitrogen is introduced onto the gate electrode 12 by the plasma nitriding process after forming the polysilicon thin film 13. This can further reduce an amount of nitrogen present near an interface between the gate insulating film 12 and the semiconductor substrate 11. Due to this, even if a thickness of the gate insulating film 12 is further reduced, it is possible to prevent deterioration in the NBTI characteristic resulting from nitrogen. Besides, since the nitrogen-containing region obtained by introducing nitrogen into the polysilicon thin film 13 is formed between the gate insulating film 12 and the gate electrode 16, it is possible to suppress the boron diffusion from the gate electrode 16 to the gate insulating film 12 and the semiconductor substrate 11.

In the above description, polysilicon is used as a material for the polysilicon thin film 13 and the polysilicon film 14. Alternatively, amorphous silicon may be used in place of polysilicon. Further, if a film to which germanium is added is formed as the gate electrode 16, an activation ratio of boron in the gate electrode 16 can be increased and the driving force of the semiconductor device can be improved.

Further, before the gate electrode 16 is formed from the polysilicon film 14, boron may be implanted into the polysilicon film 14 so as to improve gate depletion.

The introduction of nitrogen into the upper portion of the polysilicon film 14 may be performed by ion implantation. After the gate electrode 16 is formed by patterning and before the SD extensions 17 are formed, an oxide film having a thickness of about 10 nm, referred to as “offset spacer”, may be formed on the side surface of the gate electrode 16. If so, an overlap amount between the gate electrode 16 and the SD extensions 17 can be adjusted to be smaller, thereby making it possible to reduce a delay time and improve a short channel effect.

### Embodiment 2

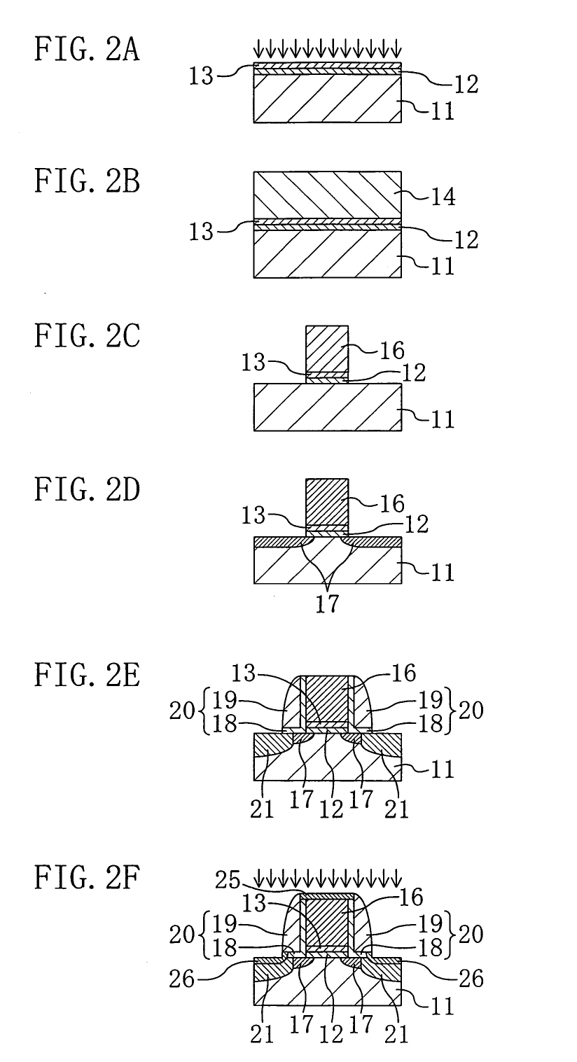

A second embodiment of the present invention will be described with reference to the drawings. FIGS. 2A to 2F are sections that depict a method for manufacturing a semiconductor device according to the second embodiment of the present invention.

In the semiconductor device manufacturing method according to the first embodiment, at a step shown in FIG. 2A, a gate insulating film 12 having a thickness of 2.0 nm is formed on a semiconductor substrate 11. Thereafter, a polysilicon thin film 13 having a thickness of 10 nm is deposited on the gate insulating film 12, and a plasma nitriding process is performed (at a pressure of 950 mT (126 Pa), at a temperature of 400° C., and for a time of 20 sec), thereby introducing nitride into the polysilicon thin film 13. At this time, by thus introducing nitrogen by the plasma nitriding process, a peak nitrogen concentration can be set at a position near an upper surface of the polysilicon thin film 13.

At a step shown in FIG. 2B, a polysilicon film 14 having a thickness of 150 nm is deposited on the polysilicon thin film 13.

At a step shown in FIG. 2C, the polysilicon film 14 is patterned by lithography and dry etching, thereby forming a gate electrode 16. At the same time, the polysilicon thin film 13 is patterned. As a result, a nitrogen-containing region obtained by introducing nitrogen into the polysilicon thin film 13 is formed between the gate insulating film 12 and the gate electrode 16. In this embodiment, the polysilicon thin film 13 is discriminated from the gate electrode 16. However, this polysilicon thin film 13 functions as a part of the gate electrode 16.

At a step shown in FIG. 2D, boron is implanted into the substrate (at an energy of 0.5 KeV and a dosage of 4×10¹⁴ cm⁻²), thereby forming SD extensions 17 in portions of the semiconductor substrate 11 which portions are located sideways of the gate electrode 16. At the same time, boron is implanted into the gate electrode 16.

At a step shown in FIG. 2E, a sidewall 20 composed of an oxide film 18 having an L-shaped cross section and a nitride film 19 located on the oxide film 18 is formed on a side surface of the gate electrode 16. Thereafter, boron is implanted into the substrate from above (at an energy of 3 KeV and a dosage of 3×10¹⁵ cm⁻²), thereby forming source-drain diffused layers 21 in portions of the semiconductor substrate 11 which portions are located sideways of the sidewall 20.

At a step shown in FIG. 2F, the plasma nitriding process is performed (at a pressure of 500 mT (67 Pa), at a temperature of 400° C., and for a time of 20 sec), thereby forming a nitrogen-containing region 25 in a region from an upper surface of the gate electrode 16 up to a depth of about 5 nm from the upper surface. At the same time, nitrogen diffused regions 26 each having a depth of 3 nm are formed in portions of a front surface portion of the semiconductor substrate 11, which portions are located sideways of the sidewall 20. Thereafter, a step of forming a silicide film and a wiring for forming a low-resistance contact is executed. However, since this step is the same as that of the conventional method, it will not be described herein.

In the semiconductor device according to the second embodiment, the nitrogen-containing region 25 in which nitrogen is present is formed on an uppermost portion of the gate electrode 16. This nitrogen-containing region 25 can prevent boron contained in the gate electrode 16 from being diffused upward of the gate electrode 16, and a boron concentration of the gate electrode 16 from being reduced. For example, even if an activation RTA treatment is performed while the gate electrode 16 is covered with a silicide protection oxide film, the nitrogen-containing region 25 can suppress the boron diffusion. Therefore, no boron is diffused from the gate electrode 16 to the silicide protection oxide film. As a result, depletion of the gate electrode 16 less occurs, and a driving force is not reduced. In addition, as compared with the first embodiment, the step of forming the nitrogen-containing region 25 on the upper portion of the gate electrode 16 is executed later. Therefore, it is possible to reduce diffusion of nitrogen by the heat treatment performed during the process. This enables nitrogen to be present in more local regions, thereby enhancing a boron diffusion prevention capability.

Meanwhile, nitrogen is introduced onto the gate insulating film 12 by the plasma nitriding process after forming the polysilicon thin film 13. This can further reduce an amount of nitrogen present near an interface between the gate insulating film 12 and the semiconductor substrate 11. Due to this, even if a thickness of the gate insulating film 12 is further reduced, it is possible to prevent deterioration in the NBTI characteristic resulting from nitrogen. Besides, since the nitrogen-containing region obtained by introducing nitrogen into the polysilicon thin film 13 is formed between the gate insulating film 12 and the gate electrode 16, it is possible to suppress the boron diffusion from the gate electrode 16 to the gate insulating film 12 and the semiconductor substrate 11.

Moreover, by forming the nitrogen diffused regions 26 on the front surface portion of the semiconductor substrate 11, it is possible to prevent boron contained in the source-drain diffused layers 21 from being diffused upward of the source-drain diffused layers 21. For example, even if an activation RTA treatment is performed while the source-drain diffused layers 21 are covered with the silicide protection oxide film, the nitrogen-containing regions 26 can suppress the boron diffusion. Therefore, no boron diffused from the source-drain diffused layers 21 to the silicide protection oxide film. As a result, the reduction in the driving force due to the reduction in impurity concentrations of the source-drain diffused layers 21 can be suppressed.

In the above description, polysilicon is used as a material for the polysilicon thin film 13 and the polysilicon film 14. Alternatively, amorphous silicon may be used in place of polysilicon. Further, if a film to which germanium is added is formed as the gate electrode 16, an activation ratio of boron in the gate electrode 16 can be increased and the driving force of the semiconductor device can be improved.

Further, before the gate electrode 16 is formed from the polysilicon film 14, boron may be implanted into the polysilicon film 14 so as to improve gate depletion.

The introduction of nitrogen into the upper portion of the gate electrode 16 may be performed by ion implantation.

After the gate electrode 16 is formed by patterning and before the SD extensions 17 are formed, an oxide film having a thickness of about 10 nm, referred to as “offset spacer”, may be formed on the side surface of the gate electrode 16. If so, an overlap amount between the gate electrode 16 and the SD extensions 17 can be adjusted to be smaller, thereby making it possible to reduce a delay time and improve a short channel effect.

### Embodiment 3

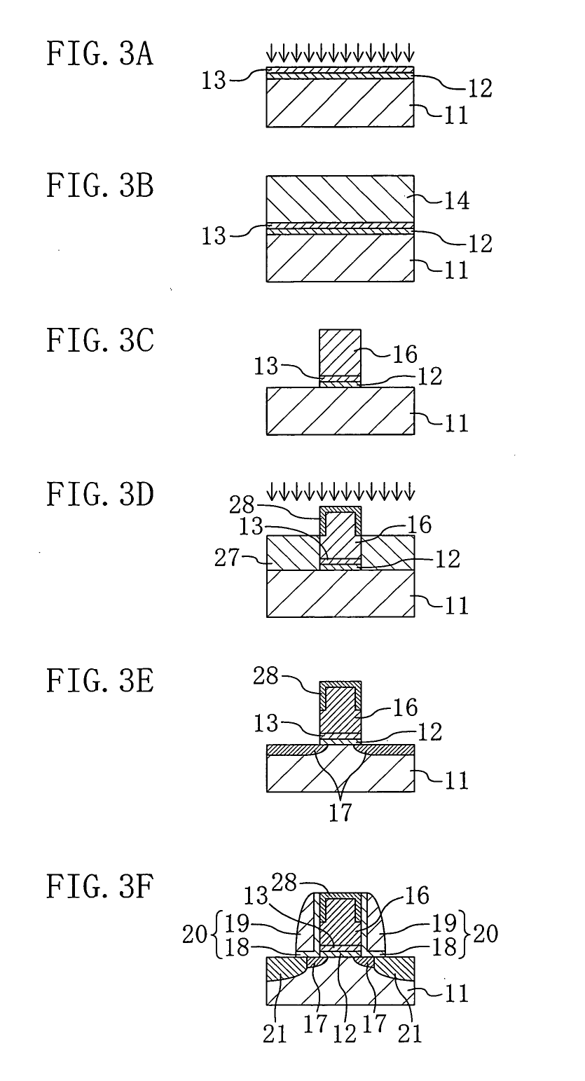

A third embodiment of the present invention will be described with reference to the drawings. FIGS. 3A to 3F are sections that depict a method for manufacturing a semiconductor device according to the third embodiment of the present invention.

In the semiconductor device manufacturing method according to the third embodiment, at a step shown in FIG. 3A, a gate insulating film 12 having a thickness of 2.0 nm is formed on a semiconductor substrate 11. Thereafter, a polysilicon thin film 13 having a thickness of 10 nm is deposited on the gate insulating film 12, and a plasma nitriding process is performed (at a pressure of 950 mT (126 Pa), at a temperature of 400° C., and for a time of 20 sec), thereby introducing nitride into the polysilicon thin film 13. At this time, by thus introducing nitrogen by the plasma nitriding process, a peak nitrogen concentration can be set at a position near an upper surface of the polysilicon thin film 13.

At a step shown in FIG. 3B, a polysilicon film 14 having a thickness of 150 nm is deposited on the polysilicon thin film 13.

At a step shown in FIG. 3C, the polysilicon film 14 is patterned by lithography and dry etching, thereby forming a gate electrode 16. At the same time, the polysilicon thin film 13 is patterned. As a result, a nitrogen-containing region obtained by introducing nitrogen into the polysilicon thin film 13 is formed between the gate insulating film 12 and the gate electrode 16. In this embodiment, the polysilicon thin film 13 is discriminated from the gate electrode 16. However, this polysilicon thin film 13 functions as a part of the gate electrode 16.

At a step shown in FIG. 3D, a resist 27 having such a thickness as to expose an upper portion of the gate electrode 16 is formed on the semiconductor substrate 11. For example, after forming the resist 27 on an entire surface of the substrate 11, the resist 27 is etched back to an extent that the upper portion of the gate electrode 16 is exposed. Thereafter, the plasma nitriding process is performed (at a pressure of 500 mT (67 Pa), at a temperature of 150° C., and for a time of 20 sec), thereby forming a nitrogen-containing region 28 having a thickness of about 3 nm in the exposed portions of the gate electrode 16. Namely, the nitrogen-containing region 28 having a thickness of about 3 nm is formed in an uppermost portion of the gate electrode 16 and a part of a side surface portion of the gate electrode 16 up to a depth halfway along the side surface portion.

At a step shown in FIG. 3E, boron is implanted into the substrate (at an energy of 0.5 KeV and a dosage of 4×10¹⁴ cm⁻²) using the gate electrode 16 as a mask, thereby forming SD extensions 17 in portions of the semiconductor substrate 11 which portions are located sideways of the gate electrode 16. At the same time, boron is implanted into the gate electrode 16.

At a step shown in FIG. 3F, a sidewall 20 composed of an oxide film 18 having an L-shaped cross section and a nitride film 19 located on the oxide film 18 is formed on a side surface of the gate electrode 16. Thereafter, boron is implanted into the substrate from above (at an energy of 3 KeV and a dosage of 3×10¹⁵ cm⁻²), thereby forming source-drain diffused layers 21 in portions of the semiconductor substrate 11 which portions are located sideways of the sidewall 20. Thereafter, a step of forming a silicide film and wiring for forming a low-resistance contact is executed. However, since this step is the same as that of the conventional method, it will not be described herein.

In the semiconductor device according to the third embodiment, the nitrogen-containing region 28 is formed on the upper portion and side surface portions of the gate electrode 16 while covering the lower portion of the gate electrode 16 and the upper portion of the semiconductor substrate 11 with the resist 27. This nitrogen-containing region 28 can prevent boron contained in the gate electrode 16 from being diffused upward and sideways of the gate electrode 16, and a boron concentration of the gate electrode 16 from being reduced. For example, even if an activation RTA treatment is performed while the gate electrode 16 is covered with a silicide protection oxide film, the nitrogen-containing region 28 can suppress the boron diffusion. Therefore, no boron is diffused from the gate electrode 16 to the silicide protection oxide film. As a result, depletion of the gate electrode 16 less occurs, and a driving force is not reduced.

Meanwhile, nitrogen is introduced onto the gate electrode 12 by the plasma nitriding process after forming the polysilicon thin film 13. This can further reduce an amount of nitrogen present near an interface between the gate insulating film 12 and the semiconductor substrate 11. Due to this, even if a thickness of the gate insulating film 12 is further reduced, it is possible to prevent deterioration in the NBTI characteristic resulting from nitrogen. In addition, nitrogen for the nitrogen-containing region 28 is introduced while covering the lower portion of the gate electrode 16 and the upper portion of the substrate 11 with the resist 27. Therefore, no nitrogen is introduced into neighborhoods of the interface between the gate insulating film 12 and the semiconductor substrate 11. It is thereby possible to prevent deterioration in the NBTI characteristic. Besides, since the nitrogen-containing region obtained by introducing nitrogen into the polysilicon thin film 13 is formed between the gate insulating film 12 and the gate electrode 16, it is possible to suppress the boron diffusion from the gate electrode 16 to the gate insulating film 12 and the semiconductor substrate 11.

In the above description, polysilicon is used as a material for the polysilicon thin film 13 and the polysilicon film 14. Alternatively, amorphous silicon may be used in place of polysilicon. Further, if a film to which germanium is added is formed as the gate electrode 16, an activation ratio of boron in the gate electrode 16 can be increased and the driving force of the semiconductor device can be improved.

Further, before the gate electrode 16 is formed from the polysilicon film 14, boron may be implanted into the polysilicon film 14 so as to improve gate depletion.

The introduction of nitrogen into the upper portion of the gate electrode 16 may be performed by ion implantation. In this embodiment, nitrogen is introduced into the upper portion of the gate electrode 16 while the upper portion of the semiconductor substrate 11 is covered with the resist 27. Therefore, even if ion implantation is performed at a strong energy, an implantation prevention capability of the resist 27 can prevent nitrogen from being introduced into the semiconductor substrate 11.

After the gate electrode 16 is formed by patterning and before the SD extensions 17 are formed, an oxide film having a thickness of about 10 nm, referred to as “offset spacer”, may be formed on the side surface of the gate electrode 16. If so, an overlap amount between the gate electrode 16 and the SD extensions 17 can be adjusted to be smaller, thereby making it possible to reduce a delay time and improve a short channel effect.

### Embodiment 4

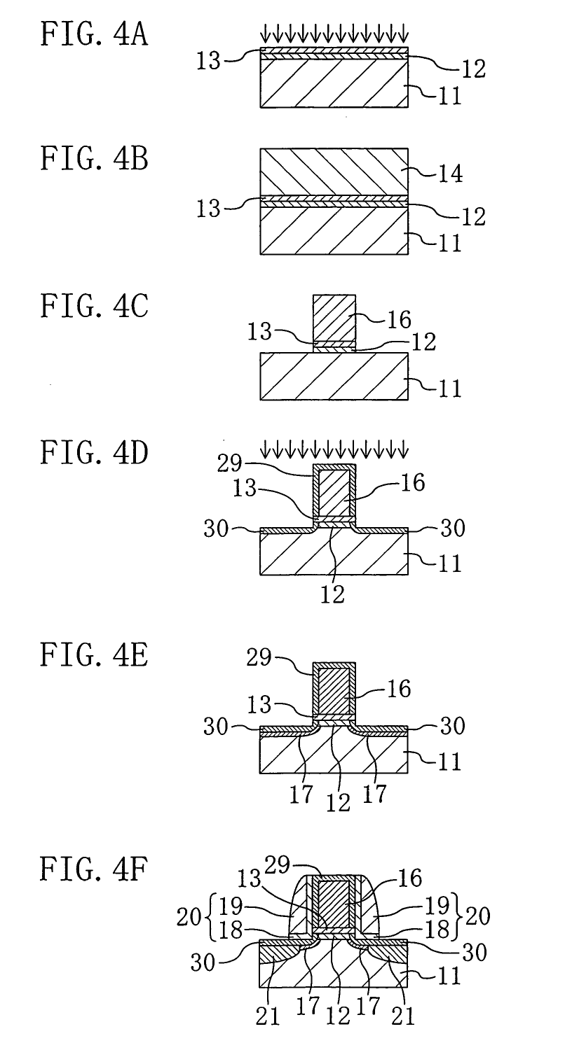

A fourth embodiment of the present invention will be described with reference to the drawings. FIGS. 4A to 4F are sections that depict a method for manufacturing a semiconductor device according to the fourth embodiment of the present invention.

In the semiconductor device manufacturing method according to the fourth embodiment, at a step shown in FIG. 4A, a gate insulating film 12 having a thickness of 2.0 nm is formed on a semiconductor substrate 11. Thereafter, a polysilicon thin film 13 having a thickness of 10 nm is deposited on the gate insulating film 12, and a plasma nitriding process is performed (at a pressure of 950 mT (126 Pa), at a temperature of 400° C., and for a time of 20 sec), thereby introducing nitride into the polysilicon thin film 13. At this time, by thus introducing nitrogen by the plasma nitriding process, a peak nitrogen concentration can be set at a position near an upper surface of the polysilicon thin film 13.

At a step shown in FIG. 4B, a polysilicon film 14 having a thickness of 150 nm is deposited on the polysilicon thin film 13.

At a step shown in FIG. 4C, the polysilicon film 14 is patterned by lithography and dry etching, thereby forming a gate electrode 16. At the same time, the polysilicon thin film 13 is patterned. As a result, a nitrogen-containing region obtained by introducing nitrogen into the polysilicon thin film 13 is formed between the gate insulating film 12 and the gate electrode 16. In this embodiment, the polysilicon thin film 13 is discriminated from the gate electrode 16. However, this polysilicon thin film 13 functions as a part of the gate electrode 16.

At a step shown in FIG. 4D, the plasma nitriding process is performed (at a pressure of 500 mT (67 Pa), at a temperature of 150° C., and for a time of 20 sec), thereby forming a nitrogen-containing region 29 having a thickness of about 3 nm in an uppermost portion and side surface portions of the gate electrode 16. At the same time, nitrogen diffused regions 30 each having a thickness of 2 nm are formed in regions of the semiconductor substrate 11, which regions are located sideways of the gate electrode 16.

At a step shown in FIG. 4E, boron is implanted into the substrate (at an energy of 0.5 KeV and a dosage of 4×10¹⁴ cm⁻²), thereby forming SD extensions 17 in portions of the semiconductor substrate 11 which portions are located sideways of the gate electrode 16. At the same time, boron is implanted into the gate electrode 16.

At a step shown in FIG. 4F, a sidewall 20 composed of an oxide film 18 having an L-shaped cross section and a nitride film 19 located on the oxide film 18 is formed on a side surface of the gate electrode 16. Thereafter, boron is implanted into the substrate from above (at an energy of 3 KeV and a dosage of 3×10¹⁵ cm⁻²), thereby forming source-drain diffused layers 21 in portions of the semiconductor substrate 11 which portions are located sideways of the sidewall 20. Thereafter, a step of forming a silicide film and a wiring for forming a low-resistance contact is executed. However, since this step is the same as that of the conventional method, it will not be described herein.

In the semiconductor device according to the fourth embodiment, the nitrogen-containing region 29 is formed in the upper portion and side surface portions of the gate electrode 16. This nitrogen-containing region 29 can prevent boron contained in the gate electrode 16 from being diffused upward or sideways of the gate electrode 16, and a boron concentration of the gate electrode 16 from being reduced. For example, even if an activation RTA treatment is performed while the gate electrode 16 is covered with a silicide protection oxide film, the nitrogen-containing region 29 can suppress the boron diffusion. Therefore, no boron is diffused from the gate electrode 16 to the silicide protection oxide film. As a result, depletion of the gate electrode 16 less occurs, and a driving force is not reduced.

Meanwhile, nitrogen is introduced onto the gate electrode 12 by the plasma nitriding process after forming the polysilicon thin film 13. This can further reduce an amount of nitrogen present near an interface between the gate insulating film 12 and the semiconductor substrate 11. Due to this, even if a thickness of the gate insulating film 12 is further reduced, it is possible to prevent deterioration in the NBTI characteristic resulting from nitrogen. Besides, since the nitrogen-containing region obtained by introducing nitrogen into the polysilicon thin film 13 is formed between the gate insulating film 12 and the gate electrode 16, it is possible to suppress the boron diffusion from the gate electrode 16 to the gate insulating film 12 and the semiconductor substrate 11.

Further, by forming the nitrogen diffused regions 30 in the front surface portions of the semiconductor substrate 11, it is possible to prevent boron contained in the source-drain diffused layers 21 from being diffused upward of the source-drain diffused layers 21. For example, even if an activation RTA treatment is performed while the source-drain diffused layers 21 are covered with a silicide protection oxide film, the nitrogen containing region 30 can suppress the boron diffusion. Therefore, no boron is diffused from the source-drain diffused layer 21 to the silicide protection oxide film. It is thereby possible to suppress a reduction in the driving force due to the reduction in the impurity concentrations of the source-drain diffused layers 21.

In the above description, polysilicon is used as a material for the polysilicon thin film 13 and the polysilicon film 14. Alternatively, amorphous silicon may be used in place of polysilicon. Further, if a film to which germanium is added is formed as the gate electrode 16, an activation ratio of boron in the gate electrode 16 can be increased and the driving force of the semiconductor device can be improved.

Further, before the gate electrode 16 is formed from the polysilicon film 14, boron may be implanted into the polysilicon film 14 so as to improve gate depletion.

The introduction of nitrogen into the upper portion of the gate electrode 16 may be performed by ion implantation.

After the gate electrode 16 is formed by patterning and before the SD extensions 17 are formed, an oxide film having a thickness of about 10 nm, referred to as “offset spacer”, may be formed on the side surface of the gate electrode 16. If so, an overlap amount between the gate electrode 16 and the SD extensions 17 can be adjusted to be smaller, thereby making it possible to reduce a delay time and improve a short channel effect.

### Embodiment 5

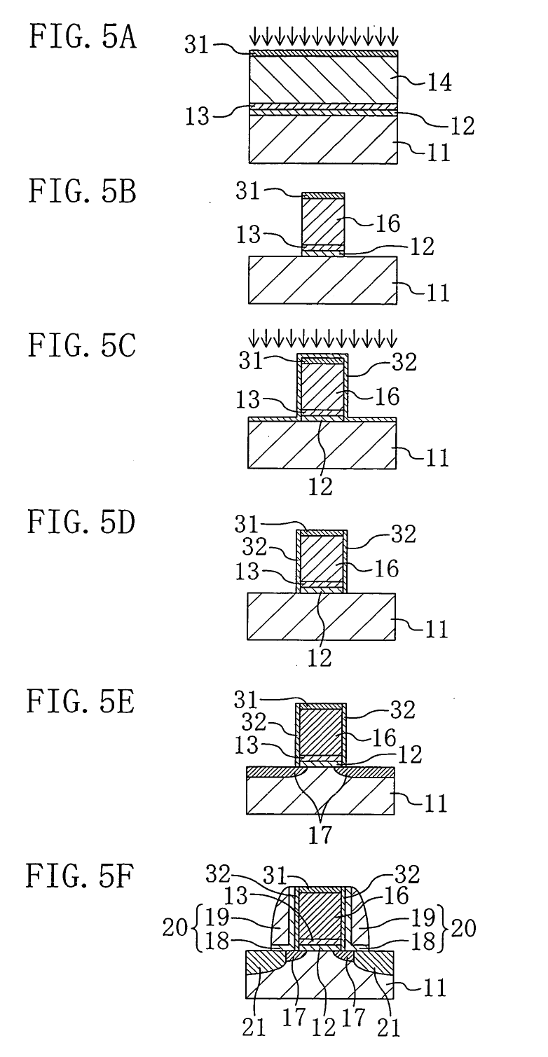

A fifth embodiment of the present invention will be described with reference to the drawings. FIGS. 5A to 5F are sections that depict a method for manufacturing a semiconductor device according to the fifth embodiment of the present invention.

In the semiconductor device manufacturing method according to the fifth embodiment, at a step shown in FIG. 5A, a gate insulating film 12 having a thickness of 2.0 nm is formed on a semiconductor substrate 11. Thereafter, a polysilicon thin film 13 having a thickness of 10 nm is deposited on the gate insulating film 12, and a plasma nitriding process is performed (at a pressure of 950 mT (126 Pa), at a temperature of 400° C., and for a time of 20 sec), thereby introducing nitride into the polysilicon thin film 13. At this time, by thus introducing nitrogen by the plasma nitriding process, a peak nitrogen concentration can be set at a position near an upper surface of the polysilicon thin film 13. Thereafter, a polysilicon film 14 having a thickness of 150 nm is deposited on the polysilicon thin film 13, and the plasma nitriding process is performed (at a pressure of 500 mT (67 Pa), at a temperature of 400° C., and for a time of 20 sec), thereby forming a nitride-containing region 31 from an upper surface of the polysilicon film 14 up to a depth of about 5 nm from the upper surface.

At a step shown in FIG. 5B, the polysilicon film 14 is patterned by lithography and dry etching, thereby forming a gate electrode 16. At the same time, the polysilicon thin film 13 is patterned. As a result, a nitrogen-containing region obtained by introducing nitrogen into the polysilicon thin film 13 is formed between the gate insulating film 12 and the gate electrode 16. In this embodiment, the polysilicon thin film 13 is discriminated from the gate electrode 16. However, this polysilicon thin film 13 functions as a part of the gate electrode 16.

At a step shown in FIG. 5C, an oxide thin film 32 having a thickness of 3 nm is formed to cover an upper portion of the semiconductor substrate 11 and a side surface and an upper surface of the gate electrode 16. The plasma nitriding process then is performed (at a pressure of 500 mT (67 Pa), at a temperature of 400° C., and for a time of 20 sec), thereby introducing nitrogen into the oxide thin film 32.

At a step shown in FIG. 5D, portions of the nitrogen-containing oxide thin film 32 which portions are located on the upper surface of the gate electrode 16 and on the upper surface of the semiconductor substrate 11 are removed by dry etching, thereby leaving the nitrogen-containing oxide thin film 32 only on the side surface of the gate electrode 16. The reason for removing the nitrogen-containing oxide thin film 32 on the upper surface of the semiconductor substrate 11 at this step is to implant boron at quite a low energy without loss at a later step (shown in FIG. 5E) of forming SD extensions 17. In other words, if the oxide film is present on the semiconductor substrate 11, boron cannot be sufficiently implanted into the semiconductor substrate 11. For this reason, the nitrogen-containing oxide thin film 32 that is the oxide film is removed before the boron implantation.

At the step shown in FIG. 5E, boron is implanted into the substrate (at an energy of 0.5 KeV and a dosage of 4×10¹⁴ cm⁻²) using the gate electrode 16 as a mask, thereby forming the SD extensions 17 in portions of the semiconductor substrate 11 which portions are located sideways of the gate electrode 16. At this time, the nitrogen-containing oxide thin film 32 also functions as a mask for the boron implantation.

At a step shown in FIG. 5F, a sidewall 20 composed of an oxide film 18 having an L-shaped cross section and a nitride film 19 located on the oxide film 18 is formed on the side surface of the gate electrode 16. Thereafter, boron is implanted into the substrate from above (at an energy of 3 KeV and a dosage of 3×10¹⁵ cm⁻²), thereby forming source-drain diffused layers 21 in portions of the semiconductor substrate 11 which portions are located sideways of the sidewall 20. Thereafter, a step of forming a silicide film and a wiring for forming a low-resistance contact is executed. However, since this step is the same as that of the conventional method, it will not be described herein.

In the semiconductor device according to the fifth embodiment, the nitrogen-containing region 31 in which nitrogen is present is formed in the uppermost portion of the gate electrode 16, and the nitrogen-containing oxide thin film 32 is formed on the side surface of the gate electrode 16. The nitrogen-containing region 31 and nitrogen-containing oxide thin film 32 can prevent boron contained in the gate electrode 16 from being diffused upward or sideways of the gate electrode 16, and a boron concentration of the gate electrode 16 from being reduced. For example, even if an activation RTA treatment is performed while the gate electrode 16 is covered with a silicide protection oxide film, the nitrogen-containing region 31 can suppress boron from being diffused from the gate electrode 16 to the silicide protection oxide film. Further, the nitrogen-containing oxide thin film 32 can suppress boron from being diffused from the gate electrode 16 to the L-shaped oxide film 18. As a result, depletion of the gate electrode 16 less occurs, and a driving force is not reduced.

Meanwhile, nitrogen is introduced onto the gate electrode 12 by the plasma nitriding process after forming the polysilicon thin film 13. This can further reduce an amount of nitrogen present near an interface between the gate insulating film 12 and the semiconductor substrate 11. Due to this, even if a thickness of the gate insulating film 12 is further reduced, it is possible to prevent deterioration in the NBTI characteristic resulting from nitrogen. Besides, since the nitrogen-containing region obtained by introducing nitrogen into the polysilicon thin film 13 is formed between the gate insulating film 12 and the gate electrode 16, it is possible to suppress the boron diffusion from the gate electrode 16 to the gate insulating film 12 and the semiconductor substrate 11.

In the above description, polysilicon is used as a material for the polysilicon thin film 13 and the polysilicon film 14. Alternatively, amorphous silicon may be used in place of polysilicon. Further, if a film to which germanium is added is formed as the gate electrode 16, an activation ratio of boron in the gate electrode 16 can be increased and the driving force of the semiconductor device can be improved.

Further, before the gate electrode 16 is formed from the polysilicon film 14, boron may be implanted into the polysilicon film 14 so as to improve gate depletion.

The introduction of nitrogen into the upper portion of the polysilicon film 14 may be performed by ion implantation. After the gate electrode 16 is formed by patterning and before the SD extensions 17 are formed, an oxide film having a thickness of about 10 nm, referred to as “offset spacer”, may be formed on the side surface of the gate electrode 16. If so, an overlap amount between the gate electrode 16 and the SD extensions 17 can be adjusted to be smaller, thereby making it possible to reduce a delay time and improve a short channel effect.

### Embodiment 6

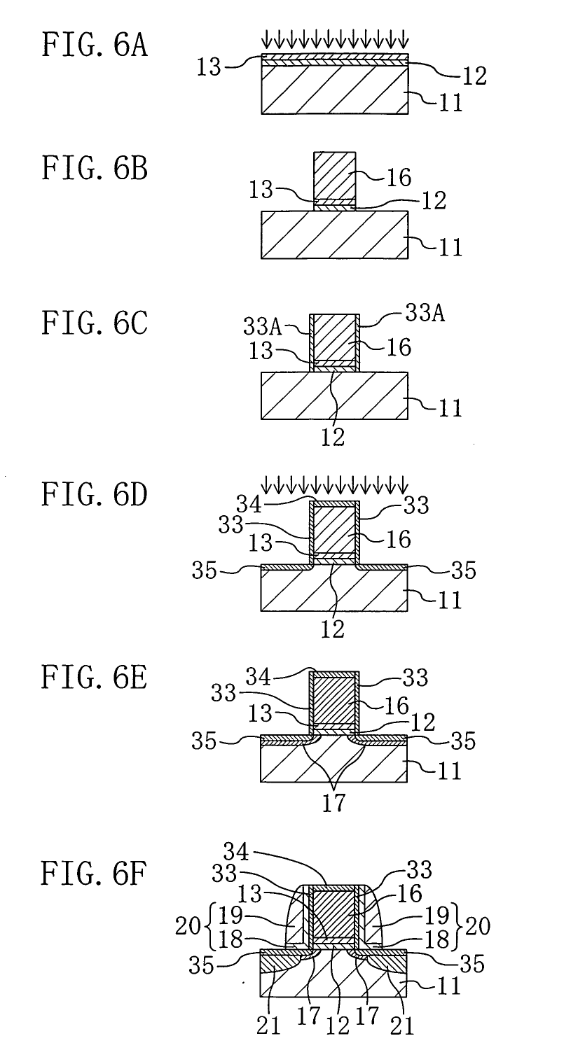

A sixth embodiment of the present invention will be described with reference to the drawings. FIGS. 6A to 6F are sections that depict a method for manufacturing a semiconductor device according to the sixth embodiment of the present invention.

In the semiconductor device manufacturing method according to the sixth embodiment, at a step shown in FIG. 6A, a gate insulating film 12 having a thickness of 2.0 nm is formed on a semiconductor substrate 11. Thereafter, a polysilicon thin film 13 having a thickness of 10 nm is deposited on the gate insulating film 12, and a plasma nitriding process is performed (at a pressure of 950 mT (126 Pa), at a temperature of 400° C., and for a time of 20 sec), thereby introducing nitride into the polysilicon thin film 13. At this time, by thus introducing nitrogen by the plasma nitriding process, a peak nitrogen concentration can be set at a position near an upper surface of the polysilicon thin film 13.

At a step shown in FIG. 6B, a polysilicon film (not shown) having a thickness of 150 nm is deposited on the polysilicon thin film 13. The polysilicon film is then patterned by lithography and dry etching, thereby forming a gate electrode 16. At the same time, the polysilicon thin film 13 is patterned. As a result, a nitrogen-containing region obtained by introducing nitrogen into the polysilicon thin film 13 is formed between the gate insulating film 12 and the gate electrode 16. In this embodiment, the polysilicon thin film 13 is discriminated from the gate electrode 16. However, this polysilicon thin film 13 functions as a part of the gate electrode 16.

At a step shown in FIG. 6C, an oxide thin film (not shown) having a thickness of 3 nm is formed to cover an upper portion of the semiconductor substrate 11 and a side surface and an upper surface of the gate electrode 16. Portions of the oxide thin film which portions are located on the upper surface of the gate electrode 16 and on the upper surface of the semiconductor substrate 11 are removed by dry etching, thereby leaving the oxide thin film on the side surface of the gate electrode 16. The reason for removing the oxide thin film on the upper surface of the semiconductor substrate 11 at this step is to implant boron at quite a low energy without loss at a later step (shown in FIG. 6E) of forming SD extensions 17. In other words, if the oxide film is present on the semiconductor substrate 11, boron cannot be sufficiently implanted into the semiconductor substrate 11. For this reason, the oxide thin film that is the oxide film is removed before the boron implantation. Alternatively, at this step, after forming the oxide thin film and before the dry etching, a plasma nitriding process may be performed to introduce nitrogen into the oxide thin film.

At a step shown in FIG. 6D, the plasma nitriding process is performed (at a pressure of 500 mT (67 Pa), at a temperature of 400° C., and for a time of 20 sec), thereby forming a nitrogen-containing region 34 on the upper surface of the gate electrode 16. In addition, nitrogen is also introduced into the oxide thin film 33A, thereby forming a nitrogen-containing oxide thin film 33 and a nitrogen diffused regions 35 in portions of the semiconductor substrate 11 which portions are located sideways of the gate electrode 16.

At a step shown in FIG. 6E, boron is implanted into the substrate (at an energy of 0.5 KeV and a dosage of 4×10¹⁴ cm⁻²) using the gate electrode 16 as a mask, thereby forming SD extensions 17 in portions of the semiconductor substrate 11 which portions are located sideways of the gate electrode 16.

At a step shown in FIG. 6F, a sidewall 20 composed of an oxide film 18 having an L-shaped cross section and a nitride film 19 located on the oxide film 18 is formed on a side surface of the gate electrode 16. Thereafter, boron is implanted into the substrate from above (at an energy of 3 KeV and a dosage of 3×10¹⁵ cm⁻²), thereby forming source-drain diffused layers 21 in portions of the semiconductor substrate 11 which portions are located sideways of the sidewall 20. Thereafter, a step of forming a silicide film and a wiring for forming a low-resistance contact is executed. However, since this step is the same as that of the conventional method, it will not be described herein.

In the semiconductor device according to the sixth embodiment, the nitrogen-containing region 34 in which nitrogen is present is formed in the uppermost portion of the gate electrode 16, and a nitrogen-containing oxide thin film 33 is formed on the side surface of the gate electrode 16. The nitrogen-containing region 34 and the nitrogen-containing oxide thin film 33 can prevent boron contained in the gate electrode 16 from being diffused upward or sideways of the gate electrode 16, and a boron concentration of the gate electrode 16 from being reduced. For example, even if an activation RTA treatment is performed while the gate electrode 16 is covered with a silicide protection oxide film, the nitrogen-containing region 34 can suppress boron from being diffused from the gate electrode 16 to the silicide protection oxide film. Further, the nitrogen-containing oxide thin film 33 can suppress boron from being diffused from the gate electrode 16 to the L-shaped oxide film 18. As a result, depletion of the gate electrode 16 less occurs, and a driving force is not reduced.

Meanwhile, nitrogen is introduced onto the gate insulating film 12 by the plasma nitriding process after forming the polysilicon thin film 13. This can further reduce an amount of nitrogen present near an interface between the gate insulating film 12 and the semiconductor substrate 11. Due to this, even if a thickness of the gate insulating film 12 is further reduced, it is possible to prevent deterioration in the NBTI characteristic resulting from nitrogen. Besides, since the nitrogen-containing region obtained by introducing nitrogen into the polysilicon thin film 13 is formed between the gate insulating film 12 and the gate electrode 16, it is possible to suppress the boron diffusion from the gate electrode 16 to the gate insulating film 12 and the semiconductor substrate 11.

Further, by forming the nitrogen diffused regions 35 in the front surface portions of the semiconductor substrate 11, it is possible to prevent boron contained in the source-drain diffused layers 21 from being diffused upward of the source-drain diffused layers 21. For example, even if an activation RTA treatment is performed while the source-drain diffused layers 21 are covered with a silicide protection oxide film, the nitrogen containing region 30 can suppress the boron diffusion from the source-drain diffused layer 21 to the silicide protection oxide film. It is thereby possible to suppress a reduction in the driving force due to the reduction in the impurity concentrations of the source-drain diffused layers 21.

In the above description, polysilicon is used as a material for the polysilicon thin film 13 and the polysilicon film 14. Alternatively, amorphous silicon may be used in place of polysilicon. Further, if a film to which germanium is added is formed as the gate electrode 16, an activation ratio of boron in the gate electrode 16 can be increased and the driving force of the semiconductor device can be improved.

Further, before the gate electrode 16 is formed from the polysilicon film 14, boron may be implanted into the polysilicon film 14 so as to improve gate depletion.

The introduction of nitrogen into the upper portion of the gate electrode 16 may be performed by ion implantation.

After the gate electrode 16 is formed by patterning and before the SD extensions 17 are formed, an oxide film having a thickness of about 10 nm, referred to as “offset spacer”, may be formed on the side surface of the gate electrode 16. If so, an overlap amount between the gate electrode 16 and the SD extensions 17 can be adjusted to be smaller, thereby making it possible to reduce a delay time and improve a short channel effect.

1. A semiconductor device, comprising an element that comprises:
a semiconductor layer;
an insulating film which is provided above said semiconductor layer;
a conductor film which is provided above said insulating film, and which contains p-type impurities; and
a first nitrogen-containing region which is provided in at least part of an upper surface portion and a side surface portion of said conductor film, and which contains nitrogen.

2. The semiconductor device of claim 1,
wherein a second nitrogen-containing region, which is a nitrogen-containing conductor film, is interposed between said insulating film and said conductor film.

3. The semiconductor device of claim 1,
wherein said first nitrogen-containing region is provided within a range at a depth of equal to or more than 10 nm from an upper surface or a side surface of said conductor film.

4. The semiconductor device of claim 1,
wherein a sidewall is provided on a side surface of said conductor film,
a first impurity diffused layer that contains the p-type impurities is provided in a portion of said semiconductor layer which portion is located sideways of said conductor film, and
a second impurity diffused layer that contains the p-type impurities higher in concentration than the p-type impurities of said first impurity diffused layer is provided in a portion of said semiconductor layer which portion is located sideways of said sidewall.

5. The semiconductor device of claim 1,
wherein a third nitrogen-containing region that contains the nitrogen is provided above said second impurity diffused layer.

6. The semiconductor device of claim 1,
wherein an oxynitride film is provided on at least part of a side surface and an upper surface of said conductor film.

7. The semiconductor device of claim 1,
wherein said p-type impurities are boron.

8. The semiconductor device of claim 1,
wherein a peak concentration of the nitrogen contained in said element is equal to or higher than 5 atoms % and equal to or lower than 20 atoms %.

9. The semiconductor device of claim 1,
wherein said conductor film consists of one of polysilicon, amorphous silicon, germanium-containing polysilicon, and germanium-containing amorphous silicon.

10. The semiconductor device of claim 1,
wherein said insulating film is a gate insulating film, and
said conductor film is a gate electrode.

11. The semiconductor device of claim 1,
wherein said element is a resistance element.

12. A method for manufacturing a semiconductor device, comprising:
a step (a) of forming a gate insulating film on a semiconductor layer;
a step (b), after said step (a), of forming a conductor film above said gate insulating film;
a step (c), after said step (b), of forming a first nitrogen-containing region by introducing nitrogen into an upper portion of said conductor film;
a step (d), after said step (c), of forming a gate electrode by patterning said conductor film; and
a step (e), after said step (d), of forming a first impurity layer in a region of said semiconductor layer which region is located sideways of said gate electrode, by introducing p-type impurities into said semiconductor layer while using said gate electrode as a mask.

13. The method of claim 12, further comprising, after said step (e):
a step (f) of forming a sidewall on a side surface of said gate electrode; and
a step (g) of forming a second impurity layer in a portion of said semiconductor layer which portion is located sideways of said sidewall by introducing the p-type impurities into said semiconductor layer while using said sidewall as the mask.

14. The method of claim 12, further comprising:
a step (h), after said step (a) and before said step (b), of forming a thin film conductor layer on said gate insulating film, and of forming a second nitrogen-containing region by introducing the nitrogen into said thin film conductor layer,
wherein at said step (b), said conductor film is formed on said second nitrogen-containing region.

15. The method of claim 12, further comprising:
a step (i), after said step (d) and before said step (e), of forming an oxynitride film that covers a side surface of said gate electrode.

16. The method of claim 15,
wherein at said step (i), an oxide film that covers said gate electrode is formed on said semiconductor layer, said oxynitride film is formed by introducing nitrogen into said oxide film, and then a portion of said oxynitride film which portion is located on at least said semiconductor layer is removed.

17. The method of claim 15,
wherein at said step (i), an oxide film that covers said gate electrode is formed on said semiconductor layer, a portion of said oxide film which portion is located on at least said semiconductor layer is removed, and then said oxynitride film is formed by introducing nitrogen into said oxide film.

18. A method for manufacturing a semiconductor device, comprising:
a step (a) of forming a gate insulating film on a semiconductor layer;
a step (b), after said step (a), of forming a conductor film above said gate insulating film;
a step (c), after said step (b), of forming a gate electrode by patterning said conductor film;
a step (d), after said step (c), of forming a first nitrogen-containing region by introducing nitrogen into at least part of an upper surface portion and a side surface portion of said gate electrode; and
a step (e) of forming a first impurity layer in a region of said semiconductor layer which region is located sideways of said gate electrode by introducing p-type impurities into said semiconductor layer while using said gate electrode as a mask.

19. The method of claim 18, further comprising, after said step (e):
a step (f) of forming a sidewall on a side surface of said gate electrode; and
a step (g) of forming a second impurity layer in a portion of said semiconductor layer which portion is located sideways of said sidewall by introducing the p-type impurities into said semiconductor layer while using said sidewall as the mask.

20. The method of claim 18, further comprising:
a step (h), after said step (a) and before said step (b), of forming a thin film conductor layer on said gate insulating film, and of forming a second nitrogen-containing region by introducing the nitrogen into said thin film conductor layer,
wherein at said step (b), said conductor film is formed on said second nitrogen-containing region.

21. The method of claim 18,
wherein at said step (d), said nitrogen is introduced while a resist covers said semiconductor layer.

22. The method of claim 18,
wherein at said step (d), a third nitrogen-containing region is formed in an upper portion of said semiconductor layer.

23. A method for manufacturing a semiconductor device, comprising:
a step (a) of forming a gate insulating film on a semiconductor layer;
a step (b), after said step (a), of forming a conductor film above said gate insulating film;
a step (c), after said step (b), of forming a gate electrode by patterning said conductor film;
a step (d), after said step (c), of forming a first impurity layer in a region of said semiconductor layer which region is located sideways of said gate electrode by introducing p-type impurities into said semiconductor layer while using said gate electrode as a mask;
a step (e), after said step (d), of forming a sidewall on a side surface of said gate electrode;
a step (f) of forming a second impurity layer in a portion of said semiconductor layer which portion is located sideways of said sidewall by introducing the p-type impurities into said semiconductor layer while using said sidewall as a mask; and
a step (g), after said step (f), of forming a nitrogen-containing region in an upper portion of said gate electrode and in an upper portion of said second impurity layer in said semiconductor layer by supplying nitrogen from above said semiconductor layer.

24. The method of claim 23, further comprising:
a step (h), after said step (a) and before said step (b), of forming a thin film conductor layer on said gate insulating film, and of introducing the nitrogen into said thin film conductor layer, and
wherein at said step (b), said conductor film is formed on said thin film conductor layer.
